(19) United States
(12) Patent Application Publication
(10) Pub. No.: US 2026/0037692 A1
(43) Pub. Date: Feb. 5, 2026

(54) SYSTEM OPTIMIZATION WITH DIGITAL TWIN AND EXPERIMENTS

(71) Applicant: Dell Products L.P., Round Rock, TX (US)

(72) Inventors: IGOR DUBROVSKY, Beer Sheva (IL); MAXIM BALIN, Gan-Yavne (IL); BORIS SHPILYUCK, Ashdod (IL)

(21) Appl. No.: 18/788,289

(22) Filed: Jul. 30, 2024

(51) Int. Cl. G06F 30/27

(52) U.S. Cl. CPC G06F 30/27

(57) ABSTRACT

Methods and systems for managing systems are disclosed. To manage the systems, potential changes to the system may be simulated. The numbers and types of changes to be simulated may be selected to reduce computational expense while maintaining coverage to evaluate impacts of different types of changes on operation of the system. Once selected, a digital twin model may be used to simulate potential operation of the system as modified by the potential changes. The resulting simulation results may be analyzed to identify significance of different potential changes to the system.

### FIELD

Embodiments disclosed herein relate generally to system management. More particularly, embodiments disclosed herein relate to systems and methods to distributed systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIGS. 2A-2B show diagrams illustrating data flows in accordance with an embodiment.

FIG. 3 shows a flow diagram illustrating a method of providing computer implemented services in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing systems. The systems may be managed by simulating potential operation of the systems with a variety of different modifications.

Performing the simulations may be expensive (e.g., computationally, financially, temporally, etc.). The numbers and type of simulations to perform may be selected to identify significance of different changes to the system while reducing computational expense.

Once selected, simulations may be performed. The results of the simulations may be analyzed to identify changes to be made to the system. Once the changes are identified, the system may be updated based on the changes.

By doing so, a system in accordance with an embodiment may be more likely to provide desired computer implemented services after modification. Thus, embodiments disclosed herein may address, among others, the technical problem of unexpected system behavior for changes to operation of the system. The disclosed embodiments may do so in a computationally efficient manner that enables full exploration of change spaces to be analyzed.

In an embodiment, a method for managing a distributed system is provided. The method may include obtaining modification options for a portion of the distributed system; obtaining an objective for the portion of the distributed system; analyzing the modification options and the objective to obtain a simulation plan; simulating, using a digital twin model for the portion of the distributed system, potential changes to the portion of the distributed system defined by the simulation plan to obtain simulation results; analyzing the simulation results to obtain levels of significance for the modification options; updating operation of the portion of the distributed system using the levels of significance and the objective to obtain an updated portion of the distributed system; and providing computer implemented services using the updated portion of the distributed system.

The objective may be defined using an object function that quantifies desirability of operation of the distributed system.

Analyzing the modification options and the objective to obtain the simulation plan may include parameterizing the modification options; and generating an orthogonal matrix based on the parameterized modification options.

Simulating the potential changes may include performing, using the digital twin model, a simulation for each entry in the orthogonal matrix to obtain a corresponding simulation result.

Analyzing the simulation result may include performing an analysis of variance on the simulation results to identify significance of each of the modification options on operation of the portion of the distributed system, the analysis of variance providing quantifications for the significance of each of the modification options.

The portion of the system may include an edge system.

The modification options may include adding a first sensor, and adding a second sensor, wherein the first sensor and the second sensor are different types of sensors.

The object may be an ability to measure a phenomenon in an area proximate to the edge system.

In an embodiment, a non-transitory media is provided. The non-transitory media may include instructions that when executed by a processor cause the computer-implemented method to be performed.

In an embodiment, a data processing system is provided. The data processing system may include the non-transitory media and a processor, and may perform the computer-implemented method when the computer instructions are executed by the processor.

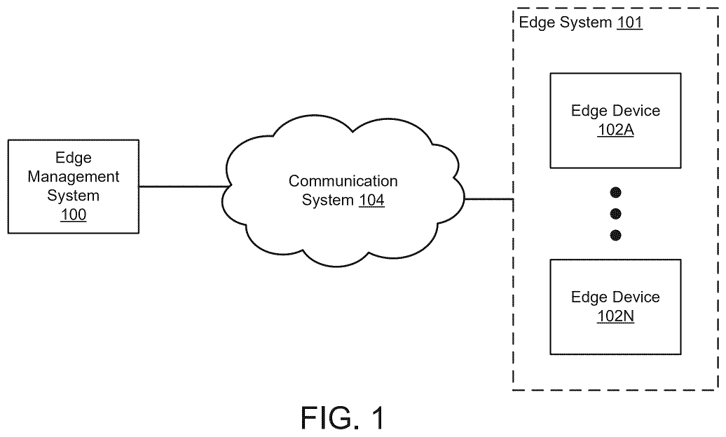

Turning to FIG. 1, a block diagram illustrating a system in accordance with an embodiment is shown. The system shown in FIG. 1 may provide computer-implemented services. The computer-implemented services may include data management services, data storage services, data access and control services, database services, and/or any other types of services that may be providing with a computing device.

To provide the services, the system may need to, for example, collect certain information, perform certain types of computations and/or algorithms, etc. For example, if a system is to provide computer implemented services that relate to a manufacturing process, temperatures of different portions of the manufacturing process may need to be measured. The temperatures may be used to analyze how well the manufacturing process is being performed.

However, if inaccurate temperature measurements are taken, then the subsequent computations performed using the temperatures measurements may also be inaccurate. Likewise, if temperature measurements cannot be taken sufficiently quickly, or exhibit lag or other undesired phenomena, then the computations may also result in undesired computation results.

To remedy these issues, sensors and/or other hardware components may be added to the system. However, mere addition of additional components may not remedy the issues in data collection and/or processing due to unaccounted for conditions impacting the system. Accordingly, if such components are purchased and added to the system, the expenditures of time, effort, and financial resources may be in vain because they may not address the issues at hand.

In general, embodiments disclosed herein may provide methods, systems, and/or devices for managing distributed systems to provide computer implemented services. To manage the distributed systems, operation of the distributed systems may be simulated using digital twin (e.g., computer simulations of real-world systems). The simulations may be used to explore how different modifications to the system are likely to impact future operation of the system. The future option may be compared to objectives and/or identify significance of the potential modifications (e.g., modification options) on operation of the system. The comparison may be used to select how to modify the system to accomplish a desired goal (e.g., as defined by the objective, which may be implemented with an objective function or other quantification schema for objectives).

To efficiently evaluate different options, a simulation plan may be established. The simulation plan may be established to limit the number of simulations that are performed to explore the modification option space. The simulation plan may be established, for example, by parameterizing the simulation options and establishing an orthogonal matrix using the parameterized options. The orthogonal matrix may define a set of simulation to be performed. Thus, only a limited number of simulations as defined by the matrix may be performed.

By doing so, embodiments disclosed herein may improve the likelihood of selected modification options positively contributing toward a defined objective. For example, using of the simulation plan may improve the likelihood that the modification option space is explored while limiting computation expenditures during simulation.

To provide the above noted functionality, the system of FIG. 1 may include edge management system 100, edge system 101, and communication system 104. Each of these components is discussed below.

Edge system 101 may be a remote system positioned near sources of data and/or otherwise away from core infrastructure such as data centers. Edge system 101 may collect information, provide various services, and/or otherwise contribute to the computer implemented services provided by the system of FIG. 1. To contribute to the services, edge system 101 may include any number of edge devices.

Edge devices (e.g., 102A-102N) may collect information relevant to other entities, process the information, and/or provide other functionalities. To collect and process the information, the edge devices may include sensors and hardware components. To meet various objectives, sensors and/or other hardware/software components of edge devices 102A-102N may be changed over time (e.g., added, removed, modified). However, the impact of these changes may be difficult to predict. Edge management system 100 may select the changes to be made through simulation of operation of edge system 101.

Edge management system 100 may manage the operation of edge system 101 by, for example, identifying modification options, selecting modification options, and instructing any of edge devices 102A-102N to update their operation based on the selected modification options. To identify desirable modification options, edge management system 100 may host digital twin models for edge system 101, and may facilitate selection and running of simulations of edge system 101 with various modification options.

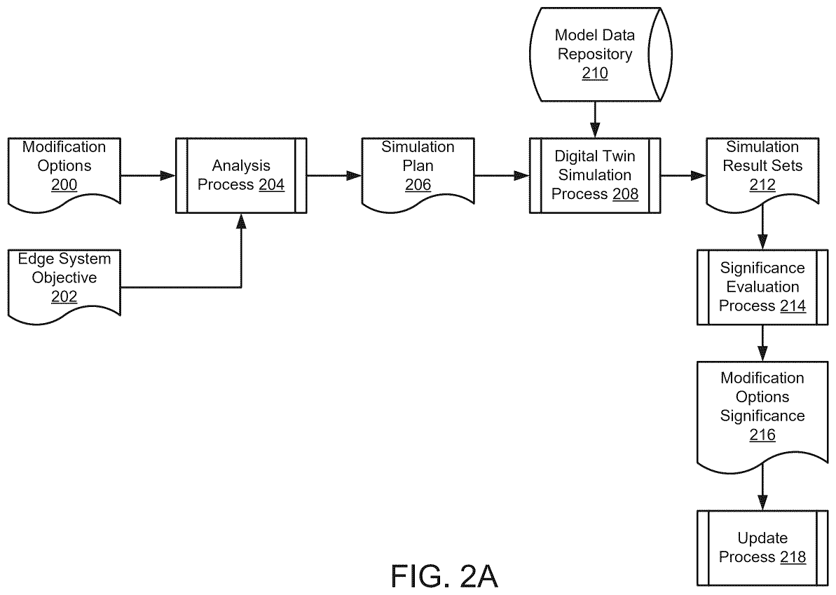

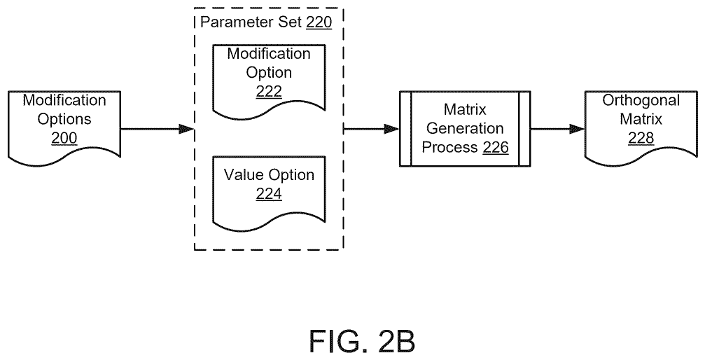

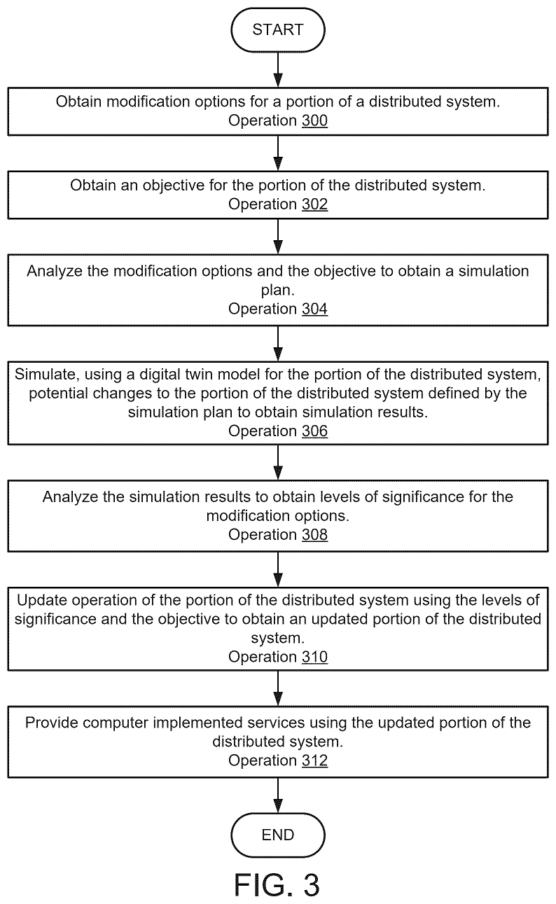

When providing their functionality, any of edge management system 100, and/or edge system 101 (and/or portions thereof) may perform all, or a portion, of the actions, flows, and methods shown in FIGS. 2A-3.

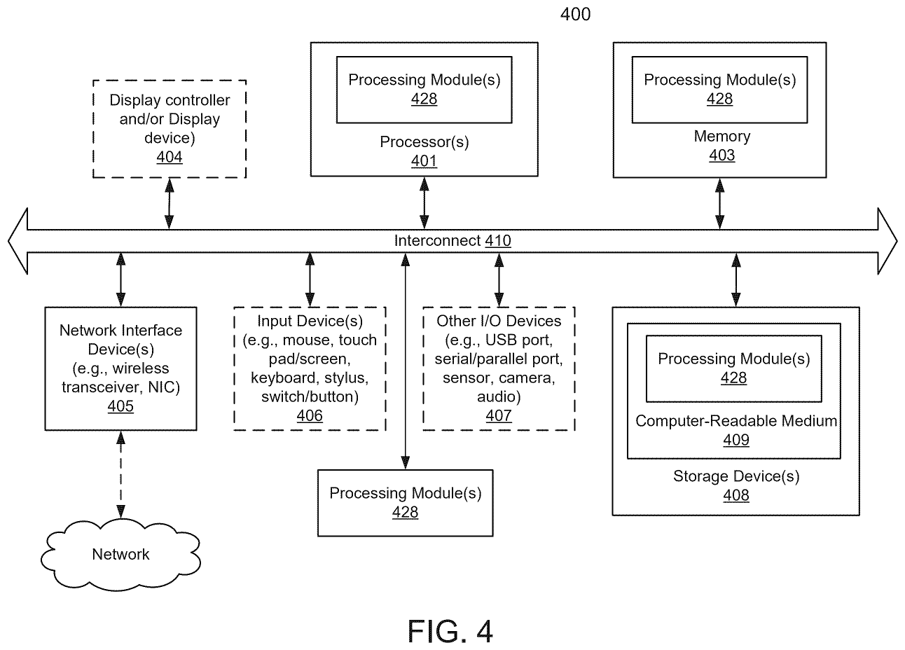

Any of (and/or components thereof) edge management system 100 and/or edge system 101 may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system. For additional details regarding computing devices, refer to FIG. 4.

Any of the components illustrated in FIG. 1 may be operably connected to each other (and/or components not illustrated) with communication system 104. In an embodiment, communication system 104 includes one or more networks that facilitate communication between any number of components. The networks may include wired networks and/or wireless networks (e.g., and/or the Internet). The networks may operate in accordance with any number and types of communication protocols (e.g., such as the internet protocol).

While illustrated in FIG. 1 as including a limited number of specific components, a system in accordance with an embodiment may include fewer, additional, and/or different components than those illustrated therein.

To further clarify embodiments disclosed herein, data flow diagrams in accordance with an embodiment are shown in FIGS. 2A-2B. In these diagrams, flows of data and processing of data are illustrated using different sets of shapes. A first set of shapes (e.g., 200, 202, etc.) is used to represent data structures, a second set of shapes (e.g., 204, 208, etc.) is used to represent processes performed using and/or that generate data, and a third set of shapes (e.g., 210, etc.) is used to represent large scale data structures such as databases.

Turning to FIG. 2A, a first data flow diagram in accordance with an embodiment is shown. The first data flow diagram may illustrate data used in and data processing performed in management of edge systems.

To manage edge systems, modification options 200 and edge system object 202 may be obtained. Modification option 200 may include any number of modification options for updating an edge system. Edge system objective 202 may specify an objective for the edge system. The data structures may be read from storage, generated (e.g., a subject matter expert may input them), and/or obtained from other devices.

Once obtained, analysis process 204 may be performed. During analysis process 204, modification options 200 and edge system objective 202 may be analyzed to obtain a simulation plan (e.g., 206). The simulation plan may specify simulations to be performed with various modification options in place in each of the simulations of operation of the edge system. Analysis process 204 may select the simulations to (i) explore the modification option space, and (ii) reduce computational expensive for completing the simulations. Refer to FIG. 2B for additional details regarding analysis process 204.

The resulting simulation plan may specify any number of simulations of operation of the edge system that are to be performed. Each of the specified simulation may include some potential modifications based on the modification options. For example, the simulation plan may specify various sensors or other hardware component additions to be included in the simulation for the edge system. Thus, the resulting simulations may be of behavior of the edge system as though various modifications had been made to it.

Once simulation plan 206 is obtained, digital twin simulation process 208 may be performed. During digital twin simulation process 208, corresponding simulations of operation of the edge system may be performed. When performing the simulations, various model parameters from model data repository 210 may be used. The model parameters may define characteristics of the existing edge system. Any of the parameters, in each simulation, may be modified based on the corresponding modification option specified in the simulation plan. Thus, the resulting performed simulations may reflect activity of the edge system if modified as specified in the corresponding modification options.

The modification options may include, for example, changes to the hardware components of the edge systems, changes to sensors and/or other types of data acquisition components, changes to configurations, changes in processing and/or control algorithms used by the edge system, etc. Thus, the simulations may reflect changes to any aspect of the edge system.

During each simulation, information may be extracted regarding the operation of the edge system. The specific information may be selected based on edge system objective 202.

For example, edge system objective 202 may include an objective function with various input parameters associated with operation of the edge system. Thus, the specific activity of the edge system monitored during the digital twin simulations may correspond to the input to the objective function of edge system objective.

Any number of resulting simulation result sets 212 may be obtained through digital twin simulation process 208. However, as noted above, the number may be limited for computational efficiency and selected to ensure that the simulation result sets allows the entire range of potential modification options to be evaluated.

Once simulation result sets 212 is obtained, significance evaluation process 214 may be performed. During significance evaluation process 214, the significance of each parameter on the edge system objective may be evaluated. For example, an analysis of variance (ANOVA) may be performed to identify the significance that each parameter has on the parameters used in the digital twin simulation process.

The resulting modification options significance 216 may quantify the impact of each parameter on the edge system objective. For example, quantifications indicating how each parameter impacts the operation of the edge system may be included in modification option significance 216.

These modification options significance values may then be used to select which modification options to proceed with.

For example, update process 218 may be performed. During update process 218, modification options significance 216 may be analyzed to select which modification options to pursue. The modification options may be selected automatically (e.g., a program may rank order and select some based on ranking), semi-automatically (e.g., the rank ordered modification options may be presented to a subject matter expert for selection), and/or manually (e.g., a subject matter expert may review modification options significance 216 and may select some based on their personal analysis).

Once selected, the modification options may be used to update operation of the edge system. For example, instructions may be sent to control planes of the edge devices of the edge system based on the modification options. Once received, automation frameworks hosted by the edge devices may update their behavior.

Similarly, if the modification options included changes to hardware, instructions may be sent to administrators, technicians, and/or other persons tasked with physical management of the edge systems. The recipients may process to change the hardware components of the edge system accordingly.

The resulting updated edge system may then proceed to provide computer implemented services using the changed hardware/software/configurations, etc.

Turning to FIG. 2B, a second data flow diagram in accordance with an embodiment is shown. The second data flow diagram may illustrate data used in and data processing performed in establishing a simulation plan (e.g., during analysis process 204).

To establish simulation plan 206, modification options 200 may be parameterized into any number of parameter sets 220. Each of the parameter sets may include a modification option (e.g., 222) and value options (e.g., 224) for the modification option. For example, if the modification option is addition of a first type of sensor, the value options may be operational parameters for the sensor (e.g., low sensitivity, medium sensitivity, high sensitivity).

Different parameter sets may correspond to different modification options. For example, to sense temperature three different types of temperature sensors may be available that each utilize different modes of sensing. In this example, three different parameter sets corresponding to the three different sensors. Further, if each of the sensors has three different operating models (e.g., low sensitivity, medium sensitivity, high sensitivity), then each value option 224 of each parameter set 220 may have three options (e.g., resulting in a 3 row by 4 column array, discussed below).

Once the parameter sets are obtained, matrix generation process 226 may be performed. During matrix generation process 226, an orthogonal matrix (e.g., 228) may be formed using the parameter sets. In this example, case, a 3 row by 4 column matrix may be created, as illustrated in Table 1, below.

TABLE 1
Example matrix elements in accordance with an embodiment.

| | | Second | Third |
|---|---|---|---|
| | First Temperature | Temperature | Temperature |
| Run | Sensor | Sensor | Sensor |
| 1 | Low Sensitivity | High Sensitivity | Low Sensitivity |
| 2 | Medium Sensitivity | Low Sensitivity | Medium Sensitivity |
| 3 | High Sensitivity | Medium Sensitivity | High Sensitivity |

Thus, as seen above, to evaluate the impact of these three temperature sensors on the ability of an edge system to obtain data usable to accomplish a desired function (e.g., as specified by an objective), three different simulations may be performed in this example.

Once obtained, orthogonal matrix 228 may be used as the simulation plan. In other words, the simulations as indicated by the matrix may be performed. In this example, each simulation may attempt to simulate the operation of the edge system as modified with the additional sensors operating in modes corresponding to each row of the matrix.

The matrix generation process 226 may be performed, for example, in accordance with the Taguchi method of evaluating alternatives.

Thus, using the flows shown in FIGS. 2A-2B, embodiments disclosed herein may facilitate selection and implementation of modifications that are more likely to result in desired operation of a system while limiting the computational expensive for selecting the modifications.

Any of the processes illustrated using the second set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor based devices (e.g., computer chips).

Any of the data structures illustrated using the first and third set of shapes may be implemented using any type and number of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

As discussed above, the components of FIG. 1 may perform various methods to provide computer implemented services using user input. FIG. 3 illustrates a method that may be performed by the components of FIG. 1. In the diagram discussed below and shown in FIG. 3, any of the operations may be repeated, performed in different orders, and/or performed in parallel with or in a partially overlapping in time manner with other operations.

Turning to FIG. 3, a flow diagram illustrating a method of managing a distributed system in accordance with an embodiment is shown. The method may be performed by any of the components of the system of FIG. 1.

At operation 300, modification options for a portion of a distributed system are obtained. The modification options may be obtained by reading them from storage, receiving them from another device, by generating them, and/or via other methods.

The modification options may be generated automatically (e.g., using an algorithm, may take into account an objective function), via a semi-automated manner (e.g., proposed by an algorithm, reviewed/approved by a subject matter expert), and/or via a manual manner (e.g., defined with input by a subject matter expert).

An objective function may be a function that quantifies desirability. The objective function may have any number of inputs, and may produce one or more outputs. One output may be a quantification (e.g., a value). The objective function may output different values for the quantification for different potential options. The values may be used to rank the different potential options with respect to each other. The form, input, and output of the objective function may be based, for example, on goals, business objectives, and/or other factors.

At operation 302, an objective for the portion of the distributed system is obtained. The objective may be obtained by reading them from storage, receiving them from another device, by generating them, and/or via other methods.

For example, an administrator or other person may specify an objective. The objective may include an objective function that quantifies desirability of operation of the portion of the distributed system.

At operation 304, the modification options and the objective are analyzed to obtain a simulation plan. The modification options and the objective may be analyzed by parameterizing the modification options; and generating an orthogonal matrix based on the parameterized modification options. The modification options may be parameterized and the orthogonal matrix may be generated using a Taguchi method.

At operation 306, potential changes to the portion of the distributed system defined by the simulation plan are simulated using a digital twin model for the portion of the distributed system to obtain simulation results. The simulation results may be input for the objective function. The potential changes may be simulated by running a number of simulations specified by the simulation plan. In each simulation, information may be extracted as the simulation results. The information may reflect operation of the portion of the distributed system as modified by at least one modification option.

At operation 308, the simulation results may be analyzed to obtain levels of significance for the modification options. The simulation results may be analyzed by performing an analysis of variance on the simulation results to identify significance of each of the modification options on operation of the portion of the distributed system, the analysis of variance providing quantifications for the significance of each of the modification options.

For example, fixed effects models, random-effects models, mixed-effects models, with various assumptions may be used. Variance algorithms may be performed to compute a number of means and variances, dividing two variances and comparing the ratio to a handbook value to determine statistical significance.

The significance of each modification option (e.g., addition of a sensor) and corresponding settings/configurations may be identified. For example, statistical measures like the F-statistic and p-value may provide insights into the level of significance each factor holds. Lower p-values may indicate a higher degree of significance and a stronger impact on system performance.

Then the most influential modification option and their optimal settings/configurations may be identified based on the analysis results.

At operation 310 operation of the portion of the distributed system is updated using the levels of significance and the objective to obtain an updated portion of the distributed system. For example, as described with respect to FIG. 2A, automated, semi-automated, and/or manual methods of identifying desirable modification options may be performed using the levels of significance to identify which modification options to select for implementation.

At operation 312, computer implemented services are provided using the updated portion of the distributed system.

The method may end following operation 312.

Using the method illustrated in FIG. 3, embodiments disclosed herein may facilitate selection and implementation of modifications to systems to facilitate provisioning of desired computer implemented services.

Any of the components illustrated in FIGS. 1-2B may be implemented with one or more computing devices. Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing a distributed system, the method comprising:
obtaining modification options for a portion of the distributed system;
obtaining an objective for the portion of the distributed system;
analyzing the modification options and the objective to obtain a simulation plan;
simulating, using a digital twin model for the portion of the distributed system, potential changes to the portion of the distributed system defined by the simulation plan to obtain simulation results;
analyzing the simulation results to obtain levels of significance for the modification options;
updating operation of the portion of the distributed system using the levels of significance and the objective to obtain an updated portion of the distributed system; and
providing computer implemented services using the updated portion of the distributed system.

2. The method of claim 1, wherein the objective is defined using an object function that quantifies desirability of operation of the distributed system.

3. The method of claim 1, wherein analyzing the modification options and the objective to obtain the simulation plan comprises:
parameterizing the modification options; and
generating an orthogonal matrix based on the parameterized modification options.

4. The method of claim 3, wherein simulating the potential changes comprises:
performing, using the digital twin model, a simulation for each entry in the orthogonal matrix to obtain a corresponding simulation result.

5. The method of claim 4, wherein analyzing the simulation result comprises:
performing an analysis of variance on the simulation results to identify significance of each of the modification options on operation of the portion of the distributed system, the analysis of variance providing quantifications for the significance of each of the modification options.

6. The method of claim 1, wherein the portion of the system comprises an edge system.

7. The method of claim 6, wherein the modification options comprises adding a first sensor, and adding a second sensor, wherein the first sensor and the second sensor are different types of sensors.

8. The method of claim 7, wherein the object is an ability to measure a phenomenon in an area proximate to the edge system.

9. A non-transitory machine-readable medium having instructions stored therein, which when executed by a processor, cause operations for managing a distributed system to be performed, the operations comprising:
obtaining modification options for a portion of the distributed system;
obtaining an objective for the portion of the distributed system;
analyzing the modification options and the objective to obtain a simulation plan;
simulating, using a digital twin model for the portion of the distributed system, potential changes to the portion of the distributed system defined by the simulation plan to obtain simulation results;
analyzing the simulation results to obtain levels of significance for the modification options;
updating operation of the portion of the distributed system using the levels of significance and the objective to obtain an updated portion of the distributed system; and
providing computer implemented services using the updated portion of the distributed system.

10. The non-transitory machine-readable medium of claim 9, wherein the objective is defined using an object function that quantifies desirability of operation of the distributed system.

11. The non-transitory machine-readable medium of claim 9, wherein analyzing the modification options and the objective to obtain the simulation plan comprises:
parameterizing the modification options; and
generating an orthogonal matrix based on the parameterized modification options.

12. The non-transitory machine-readable medium of claim 11, wherein simulating the potential changes comprises:
performing, using the digital twin model, a simulation for each entry in the orthogonal matrix to obtain a corresponding simulation result.

13. The non-transitory machine-readable medium of claim 12, wherein analyzing the simulation result comprises:
performing an analysis of variance on the simulation results to identify significance of each of the modification options on operation of the portion of the distributed system, the analysis of variance providing quantifications for the significance of each of the modification options.

14. The non-transitory machine-readable medium of claim 9, wherein the portion of the system comprises an edge system.

15. The non-transitory machine-readable medium of claim 14, wherein the modification options comprises adding a first sensor, and adding a second sensor, wherein the first sensor and the second sensor are different types of sensors.

16. The non-transitory machine-readable medium of claim 15, wherein the object is an ability to measure a phenomenon in an area proximate to the edge system.

17. A data processing system, comprising:
a processor; and
a memory coupled to the processor to store instructions, which when executed by the processor, cause operations for managing data a distributed system, the operations comprising:
obtaining modification options for a portion of the distributed system;
obtaining an objective for the portion of the distributed system;
analyzing the modification options and the objective to obtain a simulation plan;
simulating, using a digital twin model for the portion of the distributed system, potential changes to the portion of the distributed system defined by the simulation plan to obtain simulation results;
analyzing the simulation results to obtain levels of significance for the modification options;
updating operation of the portion of the distributed system using the levels of significance and the objective to obtain an updated portion of the distributed system; and
providing computer implemented services using the updated portion of the distributed system.

18. The data processing system of claim 17, wherein the objective is defined using an object function that quantifies desirability of operation of the distributed system.

19. The data processing system of claim 18, wherein analyzing the modification options and the objective to obtain the simulation plan comprises:
parameterizing the modification options; and
generating an orthogonal matrix based on the parameterized modification options.

20. The data processing system of claim 19, wherein simulating the potential changes comprises:
performing, using the digital twin model, a simulation for each entry in the orthogonal matrix to obtain a corresponding simulation result.
